(19) United States
(12) Patent Application Publication
(10) Pub. No.: US 2013/0175413 A1
(43) Pub. Date: Jul. 11, 2013

(54) Support for Camera Phones

(71) Applicant: Charles Waugh, Portland, OR (US)

(72) Inventor: Charles Waugh, Portland, OR (US)

(21) Appl. No.: 13/345,973

(22) Filed: Jan. 9, 2012

(51) Int. Cl. H05K 7/00

(52) U.S. Cl. 248/124.1; 248/316.7; 248/288.31; 248/121

(57) ABSTRACT

A support for a camera phone provides a simple way of securely cradling a wide range of camera phone sizes, irrespective of whether the phone is provided with a case. The support also provides a handle assembly for stably supporting the cradled phone by hand, or with an integrated tripod mechanism.

### BACKGROUND AND SUMMARY

This invention relates to a support for camera phones.

Mobile phones or smartphones that enable the capture of still images and video can be characterized as camera phones. Unless noted otherwise, the terms “camera phone” or “phone” will be interchangeably used here to refer to any type of mobile or smartphone that includes a camera for capturing still or video images.

The quality of images captured with conventional still or video cameras is usually improved when the camera is steadied or supported to avoid image blurring or jitter that often occurs when the camera is held by hand. Separate support of a camera also enables the photographer to move away from a camera and use the camera's remote control features for capturing images. A typical way of supporting a conventional camera is with a tripod.

Communication is the primary use of a camera phone. The phone is compact, and often carried in a pocket or purse when not in use. When used for communication, the phone is typically held by the user for permitting speaking and hearing via the respective microphone and speaker components that are built into the phone. Alternatively, the user touches a keypad on the phone for sending text messages or email via the network that is associated with the phone.

Currently popular camera phones are generally shaped as rectangular cuboids, having a length, width, and thickness that defines six rectangular faces and twelve edges. The camera phones are relatively thin as compared to the length or width. The relatively large front surface of the camera phone carries a display screen. Often, the lens of a built-in camera is exposed on the front face and/or back face of the camera phone. The display screen provides a live preview feature when the camera is operating. Various buttons and other control features are often mounted on the narrow side panels of the camera phone.

A wide variety of optional cases or “bumpers” for camera phones are available. Such cases generally enclose much of the camera phone for added protection, handling convenience, and style. A case slightly enlarges the length, width and thickness of the camera phone as compared to an uncased camera phone. With or without a case, the camera phone geometry makes it difficult to firmly grasp a camera phone while using the camera. Often, the camera phone is held between the thumbs and index fingers during use so that the display screen and camera lens are not obscured. Holding a camera phone in this manner makes it difficult to steady the phone during shooting, especially, for example, if the phone is moved while shooting a video sequence.

The present invention is directed to a support for a camera phone that provides a simple way of securely cradling a wide range of camera phone sizes and, irrespective of whether the phone is provided with a case.

The invention also provides a handle assembly for stably supporting the cradled phone either by hand or with an integrated tripod mechanism.

Other advantages and features of the present invention will become clear upon study of the following portion of this specification and drawings.

### BRIEF DESCRIPTION OF THE DRAWINGS

FIG. 1 is a perspective view of a camera phone support formed in accordance with the present invention illustrating the support cradling a phone, and with the tripod feature deployed.

FIG. 2 is a perspective, exploded view of the support, with the camera removed.

FIG. 3 is perspective view of the cradle component of the support.

FIG. 4 is a cross sectional view of the cradle component of the support taken along line 4-4 of FIG. 3.

FIG. 5 is a side view of the cradle component of the support.

FIG. 6 is a detail view of the pivot and detent mechanism associated with the tripod feature of the invention.

### DETAILED DESCRIPTION

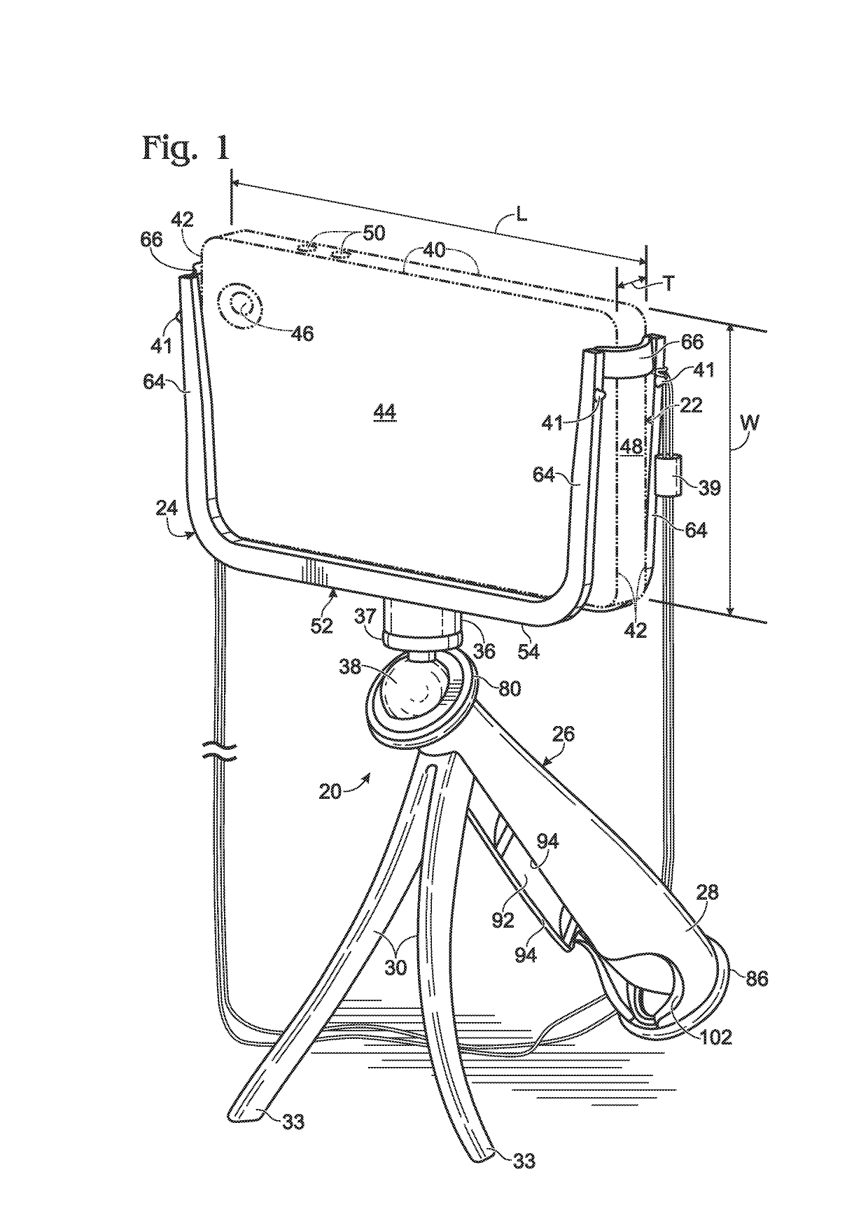

With reference to FIG. 1, a camera phone support 20 is depicted with a camera phone 22 (shown outlined in dashed lines) inserted within the cradle 24 of the support. The cradle 24 is mounted to a handle assembly 26 that includes a handle 28 and a pair of legs 30. The legs 30 are shown in a deployed position, wherein the deployed legs combine with the handle 28 to form a tripod for steadily supporting the cradle 24 and inserted camera phone 22.

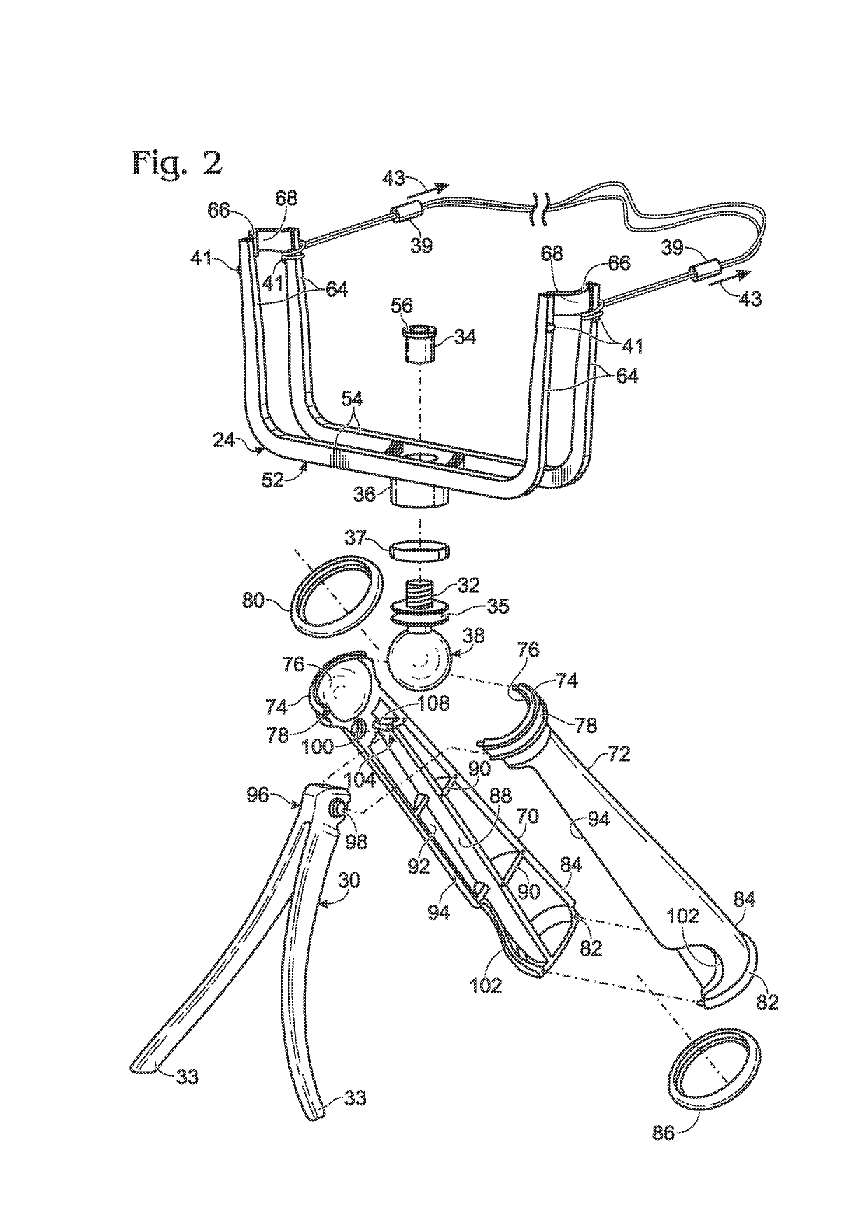

A ball head 38 is rotatably seated in one end of the handle 28. A shaft 32 having a threaded end protrudes from the ball head 38 to engage a thread insert 34 (FIG. 2) that is mounted inside of a generally cylindrical, hollow boss 36 that extends from the underside of the cradle 24.

Before discussing the particulars of the support components, it will be useful here to describe the configuration of a conventional camera phone that may be supported by the present invention. As noted earlier, the geometric shape of a camera phone (shown in dashed lines in FIG. 1) can be described as a rectangular cuboid. With reference to FIG. 1, the phone has a length dimension “L,” a width dimension “W,” and a thickness “T.” The edges of the phone are designated here as length edges 40, of which there are four, extending parallel to the length “L” of the phone. The four width edges 42 are those extending parallel to the width “W” of the phone.

The front face 44 of the phone 22 depicted in FIG. 1 includes an exposed camera lens 46. The opposite, back face (not shown) includes a touch-screen display. The back face of the phone 22 may also include another, secondary camera for capturing an image of the camera user's face, for instance. The narrow peripheral side panels 48 that extend from the front to the back face (corresponding to the thickness “T” of the phone) often carry connection or control features, such as the exemplary volume control buttons 50 shown in FIG. 1.

With reference to FIGS. 1-5, a preferred embodiment of the cradle 24 is formed of durable plastic, as by an injection molding process. The configuration of the cradle 24 is such that camera phones of various sizes can be inserted into and securely held by the cradle 24. Put another way, the cradle is not intended for use with only one, particularly sized camera phone. Rather, camera phones having a variety of length “L,” width “W,” and thickness “T” dimensions can be accommodated as will be explained later.

The cradle 24 has a base 52 that includes two elongated spaced-apart beams 54. The above-mentioned cylindrical boss 36 is integrally formed between the beams 54 (FIG. 2) at the central part of the base 52. The internally-threaded insert 34 is lodged inside the bore of the hollow boss 36. Preferably, the insert 34 is metal, such as brass, and includes an upper flange 56 that fits into a correspondingly shaped countersunk part of the bore in the boss 36. The insert may be press fit in place or bonded to the base with the use of adhesives, ultrasonic welding, etc.

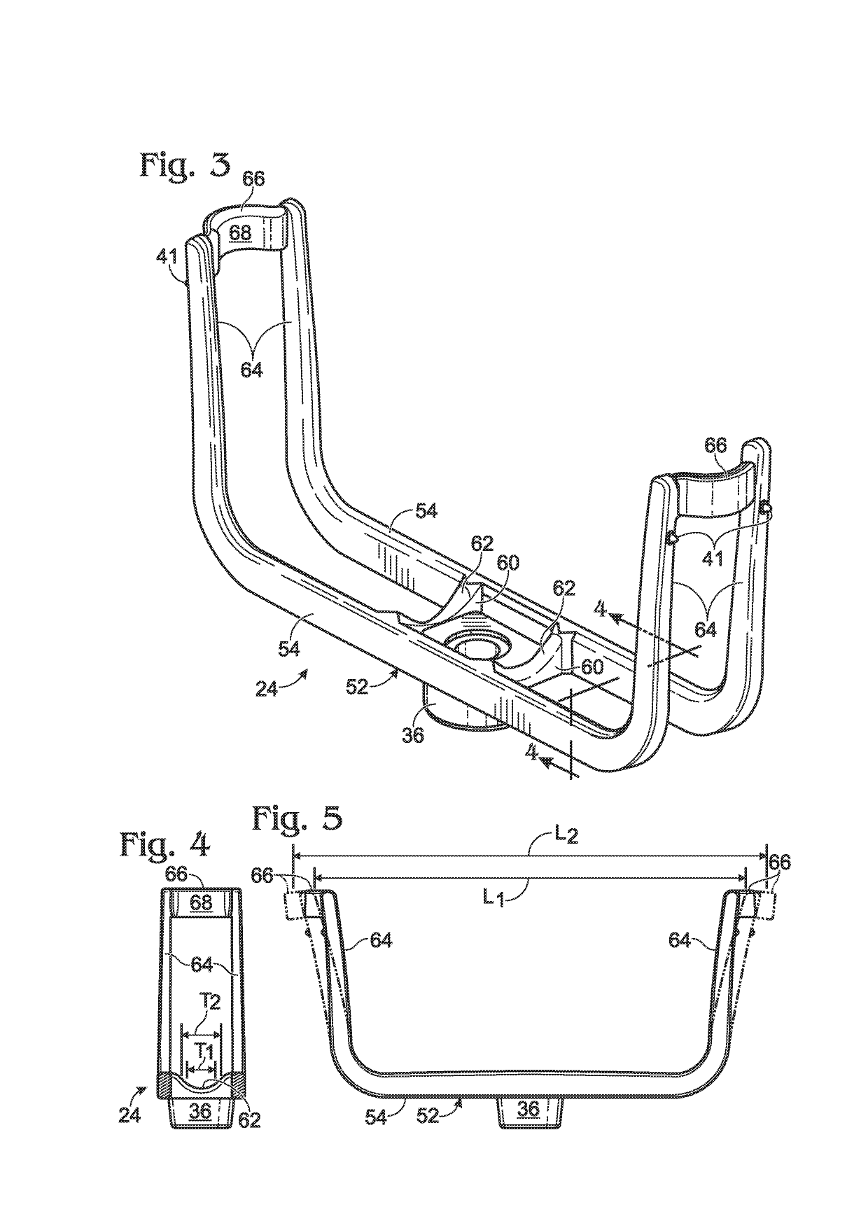

As best depicted in FIGS. 3 and 4, rest members 60 span across the two beams 54, one rest member 60 on each side of the boss 36. Each rest member 60 is integrally formed with the cradle 24 and comprises a relatively thin plate having an upwardly-facing contact surface 62 that is substantially concave shaped (FIG. 4). In a preferred embodiment, the upwardly-facing contact surfaces 62 are also tapered upwardly to form a thin, bladelike, contact surface 62 upon which rest the length edges 40 of the camera phone 22 as described more below.

At each end of the cradle base 52, the beams 54 are shaped to extend upwardly to define arms 64. Thus, at each end of the cradle base 52 a pair of spaced-apart, upwardly extending arms 64 is provided. The upper, distal ends of each arm pair are spaced apart but joined together at those ends by a curved grip member 66. The grip member 66 spans the distance between the distal ends of the arms 64. Each grip member 66 includes a concave shaped gripping surface 68. As shown in FIG. 3, the gripping surfaces 68 on the grip members 66 face inwardly, toward one another. The concave gripping surfaces 68 engage the width edges 42 of the camera phone 22 as described more below.

In the preferred embodiment, the cradle material and configuration is such that the arms 64 are resilient, normally assuming a relaxed position, as shown in solid lines in FIG. 5, but bendable out of the relaxed position into a spread position (as shown in dashed lines FIG. 5). In the relaxed position, the distance “L1” between the two gripping surfaces 68 is selected to be slightly less than the length dimension “L” of the shortest-length camera phone in the range of camera phone sizes that can be secured in the cradle. In the spread position, the distance “L2” between the two gripping surfaces 68 is slightly greater than the length dimension “L” of the longest camera phone in the range of camera phone sizes (including any additional length attributable to a case) that can be secured in the cradle 24.

It is noteworthy here that the cradle 24 can be characterized as open-ended in that the distance that the arms 64 extend from the base 52 is selected to be less than the width dimension “W” of the narrowest-width camera phone in the range of camera phone sizes that can be secured in the cradle. As a result, the opposing gripping surfaces 68 engage the width edges 42 of the camera phone with the phone protruding upwardly, beyond the upward extent of the arms 64. It will be appreciated that this open-ended configuration of the cradle essentially removes any constraints or limit on the width of camera phones that can be secured in the cradle 24.

To insert a camera phone 22 into an empty cradle 24, the arms 64 are bent slightly (dashed lines, FIG. 5) so that the grip members 66 are moved apart by an amount sufficient to allow the phone to pass between the gripping surfaces 68 until the lowermost two length edges 40 of the phone abut the concave contact surfaces 62 of the rest members 60. When released, the arms resile, and the opposing gripping surfaces 68 come into engagement with the width edges 42 on each end of the phone. It will be appreciated that the cradle arms impart a gripping force to the phone between the two grip members 66 because, owing to the relatively shorter length “L1” of the relaxed cradle as compared to that “L” of the phone, the resilient arms cannot fully return to the relaxed position and instead resile against the phone that is inserted between them.

In a preferred embodiment, the gripping surfaces 68 are formed of or coated with material that has a very high coefficient of friction, such as silicone or acrylic rubber. Such coatings are particularly useful for securing the camera phone to the cradle 24 in the event the support 20 and inserted phone 22 are inverted. That is, the resilience of the arms 64 and friction of the gripping surfaces 68 are designed to allow the support to be inverted while still securely retaining the camera phone within the cradle.

As noted above, both the gripping surfaces 68 of the grip members 66 and the contact surfaces 62 of the rest members 60 are concave shaped in the direction facing the inserted phone. This curvature provides at least three advantages. Firstly, because of this curvature, the contact between the phone 22 and surfaces 68, 62 will occur on the long edges 40 or width edges 42 of the phone. The reaction forces applied to the inserted camera 22 as a result of this contact thus provide components that prevent side-to-side motion of the camera in the cradle between the beams 54.

Secondly, the curvature of the gripping and contact surfaces permits a wide range of camera phone thicknesses to be accommodated in the cradle, while still providing the stable engagement of the edges of the camera, without side-to-side motion as mentioned above. The thickness variation is illustrated in FIG. 4, where dimensions T1 and T2 represent examples of two different phone thicknesses that can be secured in the cradle 24.

Thirdly, the edge-engaging nature of the gripping and contact surfaces enable a camera phone to be inserted and secured in the cradle without inadvertent contact or interference with buttons 50 or other controls located on the side panels 48 of the camera phone, which might otherwise occur if those gripping surfaces were planar, for example.

The concave shape of both the gripping surfaces 68 of the grip members 66 and the contact surfaces 62 of the rest members 60 need not be embodied in a smooth or continuous curve as shown in the figures. It is contemplated that the surfaces may be linear, such as V-shaped and opening outwardly, and still achieve the advantages noted above. Accordingly, the notion of the concave-shaped surface in this description is not intended to be limited to a curved shape alone.

As best shown in FIG. 1, the configuration of the cradle 24 is such that the camera phone 22 is essentially supported around its periphery, on three sides. The front face 44 and back face of the camera are both exposed so that the display/touch screen and both cameras may be used while the phone is cradled. Moreover, since the space between the cradle beams 54 and associated arms 64 is substantially open, the user will have access to the buttons and other control features that are mounted on the narrow side panels of the camera phone.

To remove an inserted phone, the distal ends of the pairs of arms 64 can be slightly bent apart for releasing the grip of the grip members 66 so that the phone can be pulled out of the cradle 24. Alternatively, a sufficient manual pulling force may be applied to the phone for overcoming the grip of the cradle without also bending the grip members apart.

As one aspect of the present invention, the exposed threads of the thread insert 34 in the cradle permit the cradle, with a camera phone inserted therein, to be attached to any conventional tripod device for obtaining the sought-after stability when capturing images and video.

As another aspect of the present invention, there is provided a versatile handle assembly that permits both tripodal support for the cradle as well as a handle that can be grasped by a hand for comfortable and stable manipulation of the cradled camera phone.

With reference to FIGS. 1 and 2 the handle assembly 26 of a preferred embodiment comprises an elongated handle 28 that is made up of two generally hollow handle parts 70, 72. The handle parts 70, 72 are preferably formed of injection molded durable plastic. The upper ends 74 of each handle part 70, 72 are formed into generally spherical sockets 76 that have smooth interior surfaces matching the curvature of the ball head 38 mentioned above.

The two handle parts 70, 72 are generally mirror images so that when brought together upon assembly (FIG. 1) the adjacent sockets 76 of the two upper ends 74 define a seat for securing the ball head 38 between the two handle parts. The combination of the two sockets 76 cover more than half of the spherical area of the ball head 38 so that the ball head is captured between the two sockets. Also, the upper ends 74 of the handle parts are sized to provide a slight gap between the upper ends 74 so that when the handle parts 70, 72 are joined together, the upper ends 74 remain slightly spaced apart so that the sockets 76 bear against the ball head 38. That is, the gapped-apart upper ends 74 can be urged toward one another, providing sufficient force between the surfaces of the sockets 76 and the ball head 38 to firmly seat the ball therein, but permitting the ball head to be forcibly rotated within the sockets for adjusting the position of the threaded shaft 32 (hence the position of the attached cradle and inserted camera) relative to the handle. The force for seating the ball is sufficient to secure the cradle and phone in the selected position regardless of whether the support is tipped or otherwise moved, as when panning to film a moving object.

A circumferential groove 78 (FIG. 2) is formed around the exterior circumference of the handle upper ends 74. The groove 78 surrounds the center of the seated ball head 38. An annular ferrule 80 is forced into the groove 78. The ferrule is configured so that when it is in the groove 78 it is under significant tension, which is transferred to the handle parts 70, 72 for securing the upper ends 74 together with the ball head 38 securely seated. Preferably, the ferrule is a dense, polymeric material that will remain taut in the groove without appreciable stretching or other deformation. The ferrule 80 can be formed of any of a variety of materials, such as polyoxymethylene.

Another circumferential groove 82 is formed in the lower ends 84 of the handle parts 70, 72, and a taut ferrule 86 is forced into that groove 82 for securing together the lower ends 84 of the handle parts 70, 72. The handle parts 70, 72 may further be fastened by adhesive or ultrasonic means along the interface between the two parts.

The handle 28 is generally hollow, but includes an integrally formed internal divider 88 (FIG. 2) that extends along the length of the handle and is stabilized there with a number of support webs 90. The internal divider 88 combines with the handle interior to define a stowage compartment 92 in the handle within which the pair of tripod legs 30 may be stowed. In this regard, the handle parts 70, 72 include recessed edges running along the length of stowage compartment 92, thereby to define an elongated slot 94 (FIG. 1) in the handle 28 and through which slot pass the tripod legs 30 legs for movement into and out of the stowage compartment 92 in a manner as described next.

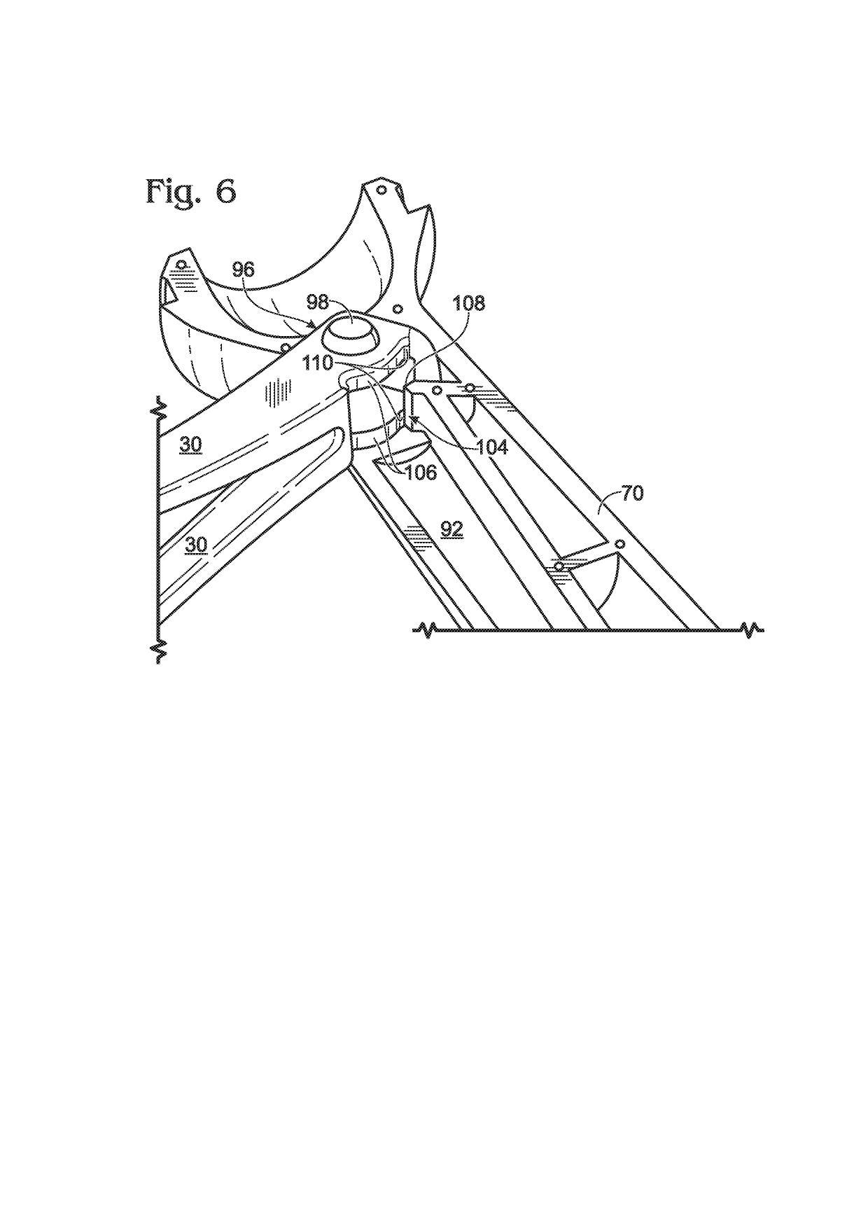

With reference to FIGS. 2 and 6, the tripod legs 30 are preferably formed of a single piece of plastic that includes a pivot head 96 where ends of both legs 30 are joined. The pivot head 96 also includes pivot posts 98 that protrude from each side of the head and that fit snugly within corresponding shaped recesses 100 formed in the upper ends 74 of both handle parts, adjacent to the ball-receiving sockets 76. The legs 30 are pivotable about the posts 98.

From the pivot head 96, the legs 30 normally splay outwardly in a curved fashion so that the free ends 33 of the legs are spaced apart from one another. As shown in FIG. 1, when the legs 30 are in this deployed position they combine with the handle 28 to form a tripod for supporting the cradle 24. It will be appreciated that the cradle 24 can be swiveled about the center of the rotatable ball head 38 so that the camera 22 can be tilted as desired while supported by the tripod.

In order to convert the handle assembly 26 into a handle 28 that can be grasped by hand (that is, so that the handle can be held in the palm of the user's hand with all fingers and thumb firmly wrapped around the handle), the legs 30 can be moved out of the deployed position and stowed in the stowage compartment 92 of the handle. Specifically, the legs 30 are sufficiently flexible so that the free ends 33 can be squeezed together for bringing the separate legs close together to fit through the slot 94 and into the stowage compartment 92 as the legs are pivoted out of the deployed position and to the stowed position, fully enclosed by the handle. As a result, the handle 28 can be firmly grasped by hand.

An annular groove 35 (FIG. 2) is formed at the base of the shaft 32 of the ball head 38. A ring 37 is fit into the groove. The ring 37 is a made of soft rubber that provides grip for the fingers of the user when attaching and disconnecting the cradle onto the threaded portion of the shaft 32. Space is provided on the shaft 32 adjacent to the ring 37. A lanyard may be secured around the stem within the space. Alternatively, (see FIG. 2) the looped ends of a lanyard 39 are looped around the upper, distal ends of two, opposing arms 64, and tightened between the grip member 66 and a retaining bump 41 formed in the end of each arm 64. (Alternatively, the lanyard ends may have hooks or any other suitable clasping elements for attaching the lanyard to the cradle.) The lanyard 39 can be worn around the neck of the user while the handle is grasped. It will be appreciated that the user may then apply tension to the lanyard 39 to increase the stability of the support 20 when the handle 28 is grasped by hand. In this regard, the tension (illustrated by arrows 43) applied to the spaced-apart lanyard ends, in combination with the user's grip on the handle 28, provides tripodal support for steadying the hand-held support 20 and prevent rotation of the cradled camera phone.

It is noteworthy that once in the stowed position, the released, free ends 33 of the legs 30 will flex apart. When this occurs, the free ends of the legs engage the interior of the housing and cannot move out of the stowage compartment 92 without further manipulation by the user. Near the lower ends 84 of the handle parts 70, 72, the slot 94 is widened into an opening 102 that is located to expose to a user's fingers enough of the free ends 33 of the stowed legs to enable the user to squeeze the free ends together so that the legs can be pulled through the slot 94 out of the stowed position and into the deployed (tripod) position.

In a preferred embodiment, the handle assembly 26 includes a detent mechanism for retaining the legs 30 in the deployed position in the absence of a predetermined minimum force applied to the handle assembly for moving the legs out of the deployed position and toward the stowed position. In this regard, when the legs 30 are fully deployed, the pivot head 96 abuts the upper end of the slot 94, which thus stops any further rotation of the legs beyond the deployed position.

As shown in FIG. 6, the detent mechanism 104 includes two curved segments 106 of the pivot head 96 portion of the legs. The curved edges of the segments 106 slide against an internal blade 108 (half of which blade—corresponding to one handle part—is shown in FIG. 6) that is formed in the handle interior. A tooth 110 protrudes from the edge of each segment 106. The teeth 110 are located so that when the legs are fully deployed, the teeth 110 will be adjacent to and bearing against the blade 108, which thus resists any pivotal motion of the legs toward the stowed position. The tooth size is selected so that with a sufficient force applied by the user, the legs can be pivoted such that the teeth 110 snap past the blade 108 to overcome the resistance to pivotal motion such that the legs may move toward the stowed position. The legs will be locked in the deployed position in the absence of such force.

While the present invention has been described in the context of preferred embodiments, it is contemplated that modifications to those embodiments may be made without departure from the invention as claimed.

1. A support for a camera phone, comprising:
a cradle having an elongated base;
a pair of arms extending from each of opposite ends of the base in a relaxed position and terminating in distal ends, each one of a pair of arms being spaced apart by a width dimension;
a grip attached between the two distal ends of each pair of arms so that the two grips are spaced apart by a length dimension and so that the grips face one another;
at least one rest member attached to the base; wherein
the arms are resilient and bendable out of the relaxed position for increasing the length dimension between the grips, thereby enabling the camera phone to be inserted between the grips and moved into contact with the rest member, and so that the arms resile with the grips against the inserted camera phone to support the camera phone in the cradle.

2. The support of claim 1 further comprising a thread insert carried by the base and configured for engaging a threaded shaft.

3. The support of claim 2 further comprising a handle assembly that includes a handle within which a ball head is seated, the ball head including a protruding threaded shaft for engaging the thread insert.

4. The support of claim 3 wherein the handle comprises two parts secured together by a taut ferrule with the ball head rotatably seated between the handle parts.

5. The support of claim 2 further comprising a handle assembly that is engageable with the thread insert, the handle assembly including a handle to which are pivotally attached two legs that are movable from a stowed position to a deployed position to form with the handle a tripod for supporting the cradle.

6. The support of claim 5 further comprising detent means for retaining the legs in the deployed position in the absence of a predetermined minimum force applied to the handle assembly for moving the legs out of the deployed position and toward the stowed position.

7. The support of claim 5 wherein the handle is substantially hollow and the legs are configured to fit inside of the handle when in the stowed position, thereby to configure the handle to be hand-graspable.

8. The support of claim 7 wherein the two legs are pivotally attached to the handle at one end of each leg, and spaced from one another at opposite, free ends of the legs when in the deployed position, the legs being flexible for squeezing together the free ends of the legs thereby to enable the legs to fit inside the hollow handle.

9. The support of claim 8 wherein the handle has an interior that is sized so that when not squeezed together, the free ends of the legs move apart and into contact with the handle interior, thereby to secure the legs within the handle interior in the stowed position.

10. The support of claim 9 wherein the handle includes an elongated slot formed therein and through which slot pass the squeezed-together legs for movement into and out of the handle interior.

11. The support of claim 9 wherein the handle includes an opening formed therein and located to expose to a user's fingers portions of the free ends of the legs stowed in the handle, thereby to enable the stowed free ends to be squeezed together and pulled out of the stowed position.

12. The support of claim 1 wherein each grip has a gripping surface, and wherein the gripping surfaces of the grips face one another, the gripping surfaces being substantially concave shaped.

13. The support of claim 1 wherein the rest member has a substantially concave shaped contact surface for contact with the inserted camera phone.

14. The support of claim 1 wherein the base comprises a pair of spaced apart beams between which extend two rest members, each rest member having a substantially concave shaped contact surface for contact with the inserted camera phone.

15. (canceled)

16. The support of claim 25 further comprising detent means for retaining the legs in the deployed position in the absence of a predetermined minimum force applied to the handle assembly for moving the legs out of the deployed position and toward the stowed position.

17. The support of claim 2515 wherein a ball head is seated in the handle, the ball head including a protruding threaded shaft for connecting the handle assembly and cradle.

18. The support of claim 17 wherein the handle comprises two parts secured together by a taut ferrule with the ball head rotatably seated between the handle parts.

19.-22. (canceled)

23. The support of claim 24 further comprising a lanyard, each opposing end of which is connected to a distal end of the pair of arms of the cradle for providing tripodal support for the support.

24. A support for a camera phone, comprising:
a cradle having an elongated base;
a pair of arms extending from each of opposite ends of the base in a relaxed position and terminating in distal ends, each one of a pair of arms being spaced apart by a width dimension;
a grip attached between the two distal ends of each pair of arms so that the two grips are spaced apart by a length dimension and so that the grips face one another;
a pair of spaced apart rest members attached in fixed positions relative to each other and to the base, each rest member defining a contact surface; wherein
the arms are resilient and movable out of the relaxed position for increasing the length dimension between the grips, thereby enabling the camera phone to be inserted between the grips and moved into contact with the contact surfaces, and so that the arms resile toward the relaxed position so that the grips bear against the inserted camera phone to support the camera phone in the cradle.

25. The support of claim 24 further comprising a handle assembly connected to the cradle and including a handle to which are pivotally attached two legs that are movable from a stowed position to a deployed position to form with the handle a tripod for supporting the cradle.
